(19) United States
(12) Patent Application Publication
(10) Pub. No.: US 2013/0206199 A1
(43) Pub. Date: Aug. 15, 2013

(54) Device and Method for Hybrid Solar-Thermal Energy Harvesting

(71) Applicants: Matthew Lassiter, Knoxville, TN (US); David Thomas, Owens Crossroads, AL (US); James Luke, Albuquerque, NM (US)

(72) Inventors: Matthew Lassiter, Knoxville, TN (US); David Thomas, Owens Crossroads, AL (US); James Luke, Albuquerque, NM (US)

(73) Assignee: AEgis Technologies Group, Inc., Huntsville, AL (US)

(21) Appl. No.: 13/572,481

(22) Filed: Aug. 10, 2012

Related U.S. Application Data
(60) Provisional application No. 61/522,995, filed on Aug. 12, 2011.

(51) Int. Cl. H01L 31/058; H01L 35/28; H01L 31/052

(52) U.S. Cl. CPC H01L 31/058; H01L 31/052; H01L 35/28
USPC 136/206

(57) ABSTRACT

A thermoelectric generator and methods of fabricating a thermoelectric generator are disclosed. An exemplary thermoelectric generator includes an upper electrode, a lower electrode, and a thermocouple disposed between the upper electrode and the lower electrode. The upper electrode, the lower electrode, and the thermocouple are configured to effect heat flux laterally through the thermocouple. In a further aspect, the thermoelectric generator is integrated with a solar cell to form a solar/thermal energy conversion device

### CROSS-REFERENCE TO RELATED APPLICATIONS

This application relates and claims priority to U.S. Provisional Patent Application No. 61/522,995 filed Aug. 12, 2011, entitled “Device and Method of Hybrid Solar-Thermal Energy Harvesting,” the entire disclosure of which is incorporated herein by reference.

### BACKGROUND

Basic concepts behind solar cells and thermoelectric generators (TEGs) are well documented. For example, satellites and spaceships have been using solar panels (for example the International Space Station) and TEGs (for example, deep space probes such as Voyager) for many years to generate electric power. Current solar cell and TEG technology is unable to produce efficient solar-thermal energy harvesting devices due to conflicting material characteristics. For example, ideally, materials needed for efficient solar-thermal energy harvesting exhibit both good electrical conductivity and poor thermal conductivity. In addition, such materials can also withstand high operating temperatures (for example, above 200° C.). Accordingly, although existing solar cells and TEGs have been generally adequate for their intended purposes, they have not been entirely satisfactory in all respects.

### SUMMARY

According to embodiments disclosed herein a thermoelectric generator includes an upper electrode; a lower electrode; and a thermocouple disposed between the upper electrode and the lower electrode. The upper electrode, the lower electrode, and the thermocouple are configured to effect heat flux laterally through the thermocouple. In a further aspect, the thermoelectric generator includes a metal substrate and an insulator layer disposed over the metal substrate, where the upper electrode, the lower electrode, and the thermocouple are disposed in the insulator layer. In yet another aspect, the thermocouple includes thermoelectric elements having a phononic nanomesh.

Further, according to embodiments disclosed herein, a solar/thermal energy conversion device includes a solar cell for generating electricity from photonic energy, and a thermoelectric generator electrically and thermally coupled with the solar cell such that the thermoelectric generator converts a portion of heat generated by the solar cell into electricity. In a further aspect, the thermoelectric generator includes an upper electrode; a lower electrode; and a thermocouple disposed between the upper electrode and the lower electrode. The upper electrode, the lower electrode, and the thermocouple are configured to effect heat flux laterally through the thermocouple.

These and other embodiments are further described below with reference to the following figures.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 depicts a Seebeck effect in different types of materials according to various aspects of the present disclosure.

FIG. 2 is a schematic circuit of a typical vertically-oriented TEG 20 according to various aspects of the present disclosure.

FIG. 3, FIG. 4, and FIG. 5 are diagrammatic views of a thermoelectric generator (TEG) according to various aspects of the present disclosure.

FIG. 6 illustrates an impact of a phononic nanomesh on phonon transport within a material layer.

FIG. 7 is a flow chart of a method for fabricating a TEG, such as the TEG of FIGS. 3-5, according to various aspects of the present disclosure.

FIG. 8 is a diagrammatic view of a hybrid solar/thermal energy generation device according to various aspects of the present disclosure.

FIG. 9 illustrates a solar panel that implements a hybrid solar/thermal energy generation device according to various aspects of the present disclosure.

FIG. 10 includes various views of a solar/laser energy collector system according to various aspects of the present disclosure.

FIG. 11 includes various views of another solar/laser energy collector system according to various aspects of the present disclosure.

### DETAILED DESCRIPTION

Embodiments described in the present disclosure relate generally to the use of solar and thermal energy and more particularly to conversion of solar and thermal energy into electrical energy.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

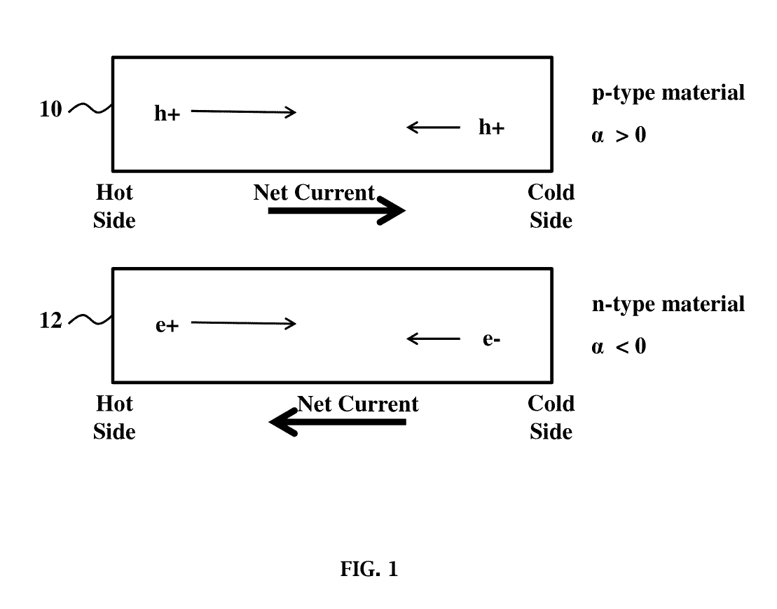

Thermoelectric power generation results from converting a temperature difference into electricity, specifically an electric voltage. Such conversion is referred to as Seebeck effect. For example, a temperature difference in a material causes free charge carriers in the material to diffuse from a hot side of the material to a cold side of the material, and vice versa. A thermoelectric voltage results from the free charge carriers migrating from the hot side to the cold side, and vice versa, of the material. FIG. 1 depicts the Seebeck effect in different types of materials, specifically a p-type semiconductor material layer 10 and an n-type semiconductor material layer 12, according to various aspects of the present disclosure. As depicted in FIG. 1, free charge carriers in the hot side of the material layers (holes (h+) in the p-type semiconductor material layer 10 and electrons (e−) in the n-type semiconductor material layer 12) have higher velocities than free charge carriers on the cold side of the material layers. The hot charge carriers thus move to the cold side of the material layers faster than the cold charge carriers move to the hot side of the material layers. This phenomenon results in a net current in the material layers and creates an electric potential difference in the p-type semiconductor material layer 10 and the n-type semiconductor material layer 12. A thermopower, or Seebeck coefficient (a), measures a magnitude of the induced thermoelectric voltage in response to the temperature difference across the material, which is defined as:

$$α = \frac{\partial V}{\partial T}$$

where ∂T is a temperature difference between the hot side and the cold side of the material layer, and ∂V is a thermoelectric voltage difference between the hot side and the cold side of the material layer. The Seebeck coefficient is thus a material and temperature dependent property. For an n-type material (such as the n-type semiconductor material layer 12), where the majority carriers are electrons, the Seebeck coefficient is negative Likewise, for a p-type material (such as the p-type semiconductor material layer 10), where the majority carriers are holes, the Seebeck coefficient is positive.

An exemplary thermoelectric power generation device is a thermoelectric generator (TEG). A TEG typically includes pairs of p-type and n-type semiconductor layers (thermoelectric materials) referred to as thermocouples. The pairs are arranged so that the TEG has alternating p-type and n-type semiconductor layers electrically in series and thermally in parallel. The pairs of p-type and n-type semiconductor layers are connected to an electrical load. This results in a circuit that generates a current when a temperature difference is maintained across ends of the thermoelectric material (specifically, a temperature difference is maintained across ends of the p-type and n-type semiconductor layers).

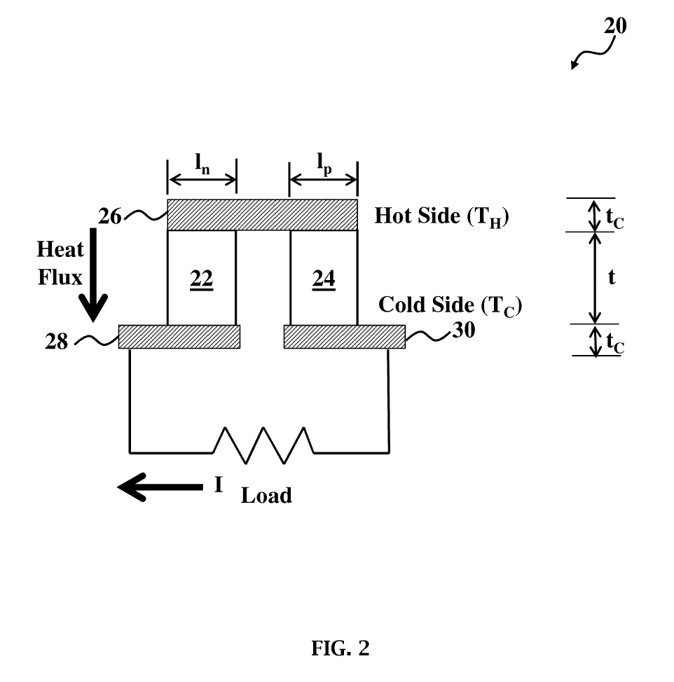

FIG. 2 is a schematic circuit of a conventional TEG 20 according to various aspects of the present disclosure. The TEG 20 includes a thermocouple (including an n-type semiconductor layer 22 and a p-type semiconductor layer 24), a top electrode 26, a bottom electrode 28, and a bottom electrode 30. The n-type semiconductor layer 22 is coupled with the top electrode 26 and the bottom electrode 28, and the p-type semiconductor layer is coupled with the top electrode 26 and the bottom electrode 30. The n-type semiconductor layer 22 and the p-type semiconductor layer 24 have a same thickness, t, and a same length, lₙ=lₚ. The top electrode 26, bottom electrode 38, and bottom electrode 30 can be referred to as contacts, each having a thickness, t_{c}. The dimensions (lₙ, lₚ, t, t_{c}) of the n-type semiconductor layer 22, p-type semiconductor layer 24, top electrode 26, bottom electrode 28, and bottom electrode 30 form a vertical “sandwich” such that the semiconductor layers 24 and 26 are sandwiched between the electrodes 22, 24, and 26. The dimensions (lₙ, lₚ, t, t_{c}) further orient heat flux (heat energy transfer through thermocouple element (the n-type semiconductor layer 22 and the p-type semiconductor layer 24)) vertically through the thermocouple elements of the TEG 20. Accordingly, during operation, the hot side of the TEG 20 drives electrons in the n-type semiconductor layer 22 toward the cool side, creating a current (I) through the circuit. Holes in the p-type semiconductor layer 24 then flow in the direction of the current, thereby converting thermal energy into electrical energy. The structure of the n-type semiconductor layer 22, p-type semiconductor layer 24, top electrode 26, bottom electrode 28, and bottom electrode 30 is typically repeated numerous times to form an array of thermocouples where the load is connected to thermocouples at ends of the array to form the TEG.

Efficiency (φ) of a thermoelectric device's electricity generation, such as the TEG 20, indicates electrical energy (power) delivered to the load versus thermal energy (power) delivered to the hot side of the TEG (in other words, heat energy absorbed at the hot junction of the thermoelectric device). Such efficiency is represented by:

$$ϕ = \frac{( {T}_{H} - {T}_{C} )}{{T}_{H}} [ \frac{s}{( 1 + s ) - ( \frac{{T}_{H} - {T}_{C}}{2 {T}_{H}} ) + \frac{{( 1 + s )}^{2}}{{ZT}_{H}}} ]$$

where T_{H} is a temperature of the hot side (at the hot junction) of the TEG, T_{C} is a temperature of the cold side, s is a ratio of a load resistance of the TEG to an internal resistance of the TEG, and Z is a thermoelectric figure of merit. The TEG efficiency can be optimized by matching the load resistance to internal resistance, such that the ratio of the load resistance of the TEG to the internal resistance of the TEG (s) is slightly greater than unity, occurring at a load resistance to internal TEG resistance:

$${ϕ}_{max} @ s = \sqrt{1 + Z ( \frac{{T}_{H} + {T}_{C}}{2} )}$$

where the maximized TEG efficiency (φₘₐₓ) is then represented by:

$${ϕ}_{max} = \frac{( {T}_{H} + {T}_{C} )}{{T}_{H}} ( \frac{\sqrt{1 + z ( \frac{{T}_{H} + {T}_{C}}{2} )} - 1}{\sqrt{1 + z ( \frac{{T}_{H} + {T}_{C}}{2} )} + \frac{{T}_{C}}{{T}_{H}}} )$$

The TEG efficiency can thus be improved by increasing the thermoelectric figure of merit (Z). efficiency of the For load resistances, the efficiency is improved by increasing the thermoelectric figure of merit (Z) associated with the TEG. The thermoelectric figure of merit is represented by:

$$Z = \frac{{α}^{2} σ}{κ}$$

where α is the Seebeck coefficient of the TEG, σ is electrical conductivity of the TEG, and κ is thermal conductivity of the TEG. One approach to increase the thermoelectric figure of merit is to increase the electrical conductivity. It has been observed that such approach (increasing the electrical conductivity) typically results in a proportionate increase in the thermal conductivity, and thus no observable net improvement in the thermoelectric figure of merit. Another approach is to reduce the thermal conductivity. Since heat transfer in the TEG results from both charge carrier transport (a charge carrier component) and phonon transport (a phonon component), and the heat transfer resulting from the phonon transport is generally wasted and not converted into electric energy, the present disclosure proposes a novel structure for a TEG that increases the thermoelectric figure of merit, thereby decreasing the thermal conductivity of the TEG without impacting electrical conductivity, and thus maximizing the TEG conversion efficiency. The following discussion describes such novel structure.

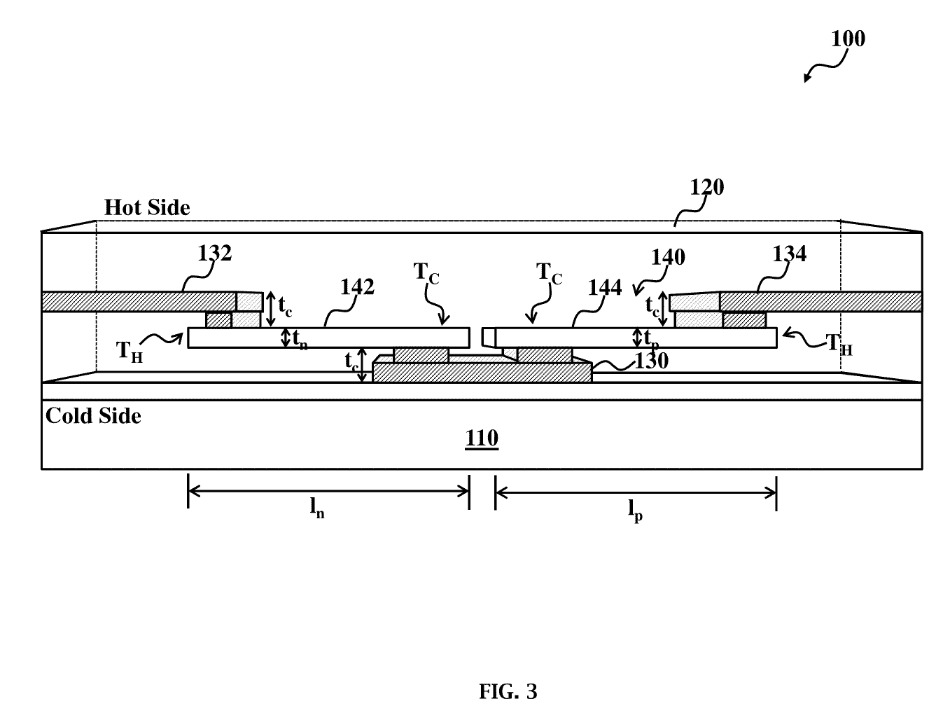

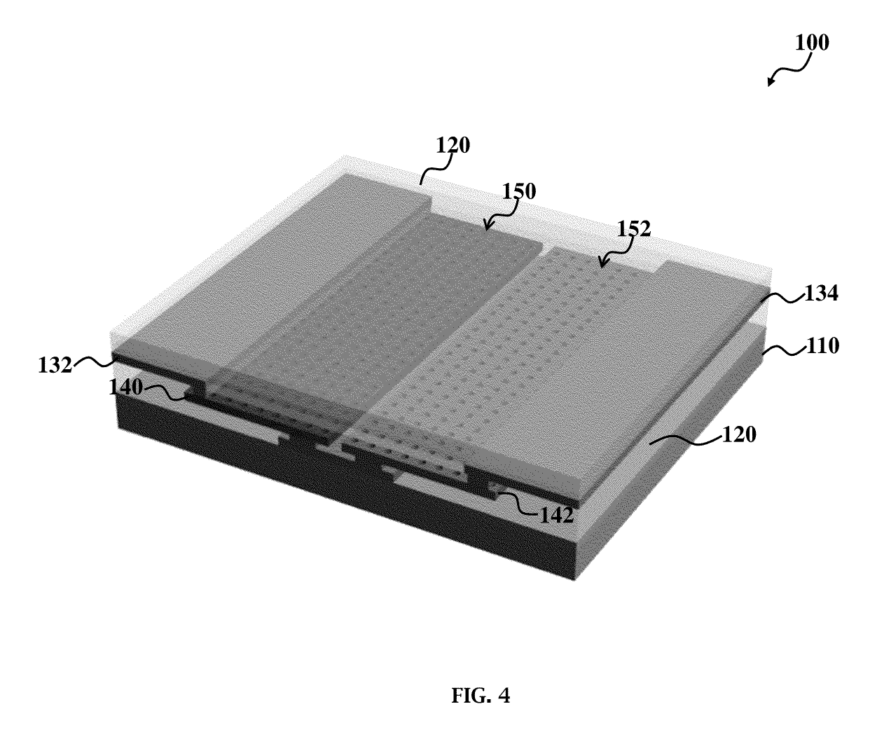

FIG. 3, FIG. 4, and FIG. 5 are diagrammatic views of a thermoelectric generator (TEG) 100, in portion or entirety, according to various aspects of the present disclosure. As described in detail below, the TEG 100 orients heat flux (heat energy transfer through thermocouple elements required for generating electric power) laterally through thermocouple elements of the TEG 100 rather than vertically through the thermocouple elements as conventional TEGs, such as that illustrated in FIG. 2 described above. By orienting the heat flux laterally through the TEG 100, maximum conversion efficiency can be achieved by the TEG 100. The TEG 100 further modifies a nanostructure of its thermocouple to increase a thermoelectric figure of merit of the TEG 100, which also maximizes conversion efficiency. FIGS. 3-5 will be discussed concurrently, and FIGS. 3-5 have been simplified for the sake of clarity to better understand the inventive concepts of the present disclosure. Additional features can be added in the TEG 100, and some of the features described below can be replaced or eliminated for additional embodiments of the TEG 100.

Conventional TEGs include ceramic substrates, which are planar and inflexible, making them unsuitable for integration with heat sources, such as solar cells, that have irregular shapes or devices requiring flexibility, such as in space-based solar panels. Flexible polymer substrates have been proposed for TEGs, however, polymer substrates cannot withstand temperatures above a glass transition temperature, T_{g}, which is about 215° C. for polycarbonates. This makes TEGs having polymer substrates impractical for application in devices with elevated operating temperatures. The present disclosure thus proposes a metal substrate 110 for the TEG 110. The metal substrate 110 includes a thermally conductive material, such as aluminum, iron, nickel, cobalt, stainless steel, other thermally conductive material, or combinations thereof (for example, KOVAR (an iron, nickel, cobalt alloy) or INVAR (an iron and nickel alloy). In the depicted embodiment, the metal substrate 110 is a metal foil substrate, such as a KOVAR metal foil. The metal substrate 110 has a thickness of about 50 μm to about 300 μm. In the depicted embodiment, the metal substrate 110 has a thickness of about 150 μm. The thin, flexible metal foil substrate 110 can withstand temperatures well above about 600° C., and potentially as high as about 1,000° C., while also providing maximum flexibility of the TEG 100, so that the TEG 100 easily conforms to shapes of devices with which the TEG 100 is integrated.

An insulator layer 120 is disposed over the substrate 110. In the depicted embodiment, the insulator layer 120 includes a dielectric material, such as silicon oxide, silicon nitride, aluminum nitride, aluminum oxide, titanium oxide (TiO₂), other dielectric material, or combinations thereof. In the depicted embodiment, the insulator layer 120 has a thickness of about 0.010 μm to about 1 μm.

An electrode 130, an electrode 132, and an electrode 134 are disposed in the insulator layer 120. In the depicted embodiment, the electrode 130 is referred to as a lower electrode, and the electrodes 132 and 134 are referred to as upper electrodes. The electrodes 130, 132, and 134 may also be referred to as contacts. The electrodes 130, 132, and 134 include a thermally conductive material, such as aluminum, gold, silver, copper, tungsten, zinc, nickel, platinum, palladium, other thermally conductive materials, or combinations thereof. In the depicted embodiment, the electrodes 130, 132, and 134 have a same thickness (t_{c}). For example, the electrodes 130, 132, and 134 have a thickness of about 50 nm to about 500 nm. Alternatively, the electrodes 130, 132, and 134 have varying thicknesses.

A thermocouple 140 is also disposed in the insulator layer 120 between the lower electrode 130 and the upper electrodes 132 and 134. The thermocouple 140 includes an n-type semiconductor layer 142 and a p-type semiconductor layer 144. The n-type semiconductor layer 142 and the p-type semiconductor layer 144 are arranged electrically in series and thermally in parallel. In the present example, the n-type semiconductor layer 142 is coupled with the bottom electrode 130 and the upper electrode 132, and the p-type semiconductor layer 144 is coupled with the bottom electrode 130 and the upper electrode 134. The n-type semiconductor layer 142 and the p-type semiconductor layer 144 include a thermoelectric semiconductor material, such as silicon, germanium, silicon germanium, bismuth telluride (Be₂Te₃), lead telluride (PbTe), Zn₄Sb₃, other thermoelectric semiconductor material, or combinations thereof. The n-type semiconductor layer 142 is doped with n-type dopants, such as phosphorous, arsenic, other n-type dopants, or a combination thereof. The p-type semiconductor layer 144 is doped with p-type dopants, such as boron, BF₂, other p-type dopants, or combinations thereof. In the depicted embodiment, the n-type semiconductor layer 142 and the p-type semiconductor layer 144 have a same thickness (tₙ=tₚ=t) and a same length (lₙ=lₚ=l). In an example, the n-type semiconductor layer 142 and the p-type semiconductor layer 144 have a thickness of about 50 nm to about 1,000 nm. Alternatively, the semiconductor layers 142 and 144 have varying thicknesses and lengths.

It has been observed that if the thermoelectric elements (here, the semiconductor layers 142 and 144) are sufficiently long effects of a TEG's electrical contacts (here, electrodes 130, 132, and 134) can be eliminated from the TEG conversion efficiency, such that maximized TEG conversion efficiency (φₘₐₓ) (where the load resistance matches the internal resistance of the TEG) can also be represented by:

$$φ = \frac{{ZT}_{H} {φ}_{c}}{( 2 {ZT}_{H} - \frac{1}{2} {ZT}_{H} {φ}_{c} + 4 )}$$

In this case, gains in the thermoelectric figure of merit (Z) increase the conversion efficiency in a linear fashion until the TEG conversion efficiency approaches maximum theoretical Carnot efficiency (φ_{c}). Taking advantage of such observation, the TEG 100 exhibits a lateral design that eliminates effects of the electrodes 130, 132, and 134 (particularly effects contributed by the thickness (t_{c}) of the electrodes 130, 132, and 134). For example, in contrast to conventional TEGs, such as TEG 20, where the electrodes sandwich the thermoelectric elements therebetween, the electrodes 130, 132, and 134 are laterally offset from the semiconductor layers 142 and 144 such that the semiconductor layers 142 and 144 are partially overlapped by the electrodes 130, 132, and 134. Put another way, the electrodes 130, 132, and 134 contact a portion of the hot and cold surfaces of the semiconductor layers 142 and 144 as opposed to the entirety of the hot and cold surfaces of the semiconductor layers 142 and 144. This laterally orients hot ends (T_{H}) and cold ends (T_{C}) of the semiconductor layers 142 and 144, such that a temperature gradient is created along the length of the semiconductor layers 142 and 144 as opposed to along the thickness (t) of the semiconductor layers 142 and 144. In the depicted embodiment, the thickness (t) of the semiconductor layers 142 and 144 is less than the length (l) of the semiconductor layers 142 and 144 to achieve the lateral temperature gradient. The present disclosure contemplates optimizing dimensions of the TEG 100 (thicknesses of the electrodes 130, 132, and 134; thicknesses of the semiconductor layers 142 and 144; and lengths of the semiconductor layers 142 and 144) to achieve a desired lateral temperature gradient while limiting parasitic heat conduction. For example, if the length of the semiconductor layers 142 and 144 is too short, less than optimal temperature gradient is achieved by the TEG 100, while if the length of the semiconductor layers 142 and 144 is too long, an increase in parasitic heat conduction reduces efficiency of the TEG 100.

The various dimensions of the TEG 100 (thicknesses of the electrodes 130, 132, and 134; thicknesses of the semiconductor layers 142 and 144; and lengths of the semiconductor layers 142 and 144) are thus designed to maximize conversion efficiency. In the depicted embodiment, configuration and dimensions of the thermocouple elements (semiconductor layers 142 and 144) relative to the contacts (electrodes 130, 132, and 134) orients heat flux (heat energy transfer through thermocouple elements required for generating electric power) laterally through the TEG 100 rather than vertically through the thermocouple elements as conventional TEGs, such as that illustrated in FIG. 2 described above. For example, in FIG. 5, heat flows laterally through the TEG 100. Primary thermal heat (designated by large thick dark arrows) flows through the thermoelectric elements (the n-type semiconductor layer 142 and the p-type semiconductor layer 144), which is used to generate electricity, and parasitic heat (designated by small thin arrows) flows through the insulator layer 120, towards the cold side of the TEG 100. By orienting the heat flux laterally through the TEG 100, maximum conversion efficiency can be achieved by the TEG 100.

Further, as discussed above, efficiency of a TEG, such as the TEG 100, is also improved by increasing a thermoelectric figure of merit (Z) associated with the TEG. The thermoelectric figure of merit is represented by:

$$Z = \frac{{α}^{2} σ}{κ}$$

where α is a Seebeck coefficient of the TEG, σ is electrical conductivity of the TEG, and κ is thermal conductivity of the TEG. One approach to increase the thermoelectric figure of merit is to increase the electrical conductivity. It has been observed that such approach (increasing the electrical conductivity) typically results in a proportionate increase in the thermal conductivity, and thus no observable net improvement in the thermoelectric figure of merit. Another approach is to reduce the thermal conductivity. Since heat transfer in the TEG results from both charge carrier transport (a charge carrier component) and phonon transport (a phonon component), and the heat transfer resulting from the phonon transport is generally wasted and not converted into electric energy, the present disclosure proposes modifying a nanostructure of a thermocouple of the TEG to minimize (reduce) the phonon component. By minimizing the phonon component of heat transfer in the TEG, the thermal conductivity of the TEG is reduced without impacting the electrical conductivity, resulting in an increased thermoelectric figure of merit and thereby improved efficiency of the TEG.

Referring to FIG. 4, the thermocouple 140 has a nanostructure designed to minimize the phonon component of heat transfer without impacting the charge carrier component. More specifically, a nanostructure of the n-type semiconductor layer 142 and the p-type semiconductor layer 144 is modified to minimize phonon transport without impacting charge carrier transport within the semiconductor layers 142 and 144. In FIG. 4, the n-type semiconductor layer 142 includes a phononic nanomesh 150, and the p-type semiconductor layer 144 includes a phononic nanomesh 152. The phononic nanomesh 150 is an array of holes 154 in the n-type semiconductor layer 142, and the phononic nanomesh 152 is an array of holes 156 in the p-type semiconductor layer 144. Sizing and spacing of the holes 154 and 156 in their respective arrays depends on the thermoelectric material respectively of the semiconductor layers 142 and 144, and vibrational modes of the phonons the phononic nanomeshes 150 and 152 are intended to reflect. In the depicted embodiment, the holes 154 are sized and spaced on an order of a mean free path of phonons flowing in the material of the n-type semiconductor layer 142, and the holes 156 are sized and spaced on an order of a mean free path of phonons flowing in the material of the p-type semiconductor layer 144. In an example, the holes 154 and 156 have a diameter of about 5 nm to about 200 nm. In an example, a pitch of the holes 154 and 156 is about 30 nm to about 500 nm. The phononic nanomeshes 150 and 152 are further configured to scatter phonons respectively at surfaces of the semiconductor layers 142 and 144. For example, the pitch of the holes 154 and 156 is on an order of magnitude of a wavelength of the phonons, thereby creating a phonon Bragg reflector. Alternatively, a nanostructure of only the n-type semiconductor layer 142 or the p-type semiconductor layer 144 is modified to include a phononic nanomesh. It is noted that the lateral configuration of the thermoelectric elements of the TEG 100 (the semiconductor layers 142 and 144) facilitates easy integration of the phononic nanomeshes 150 and 152 into the thermoelectric elements.

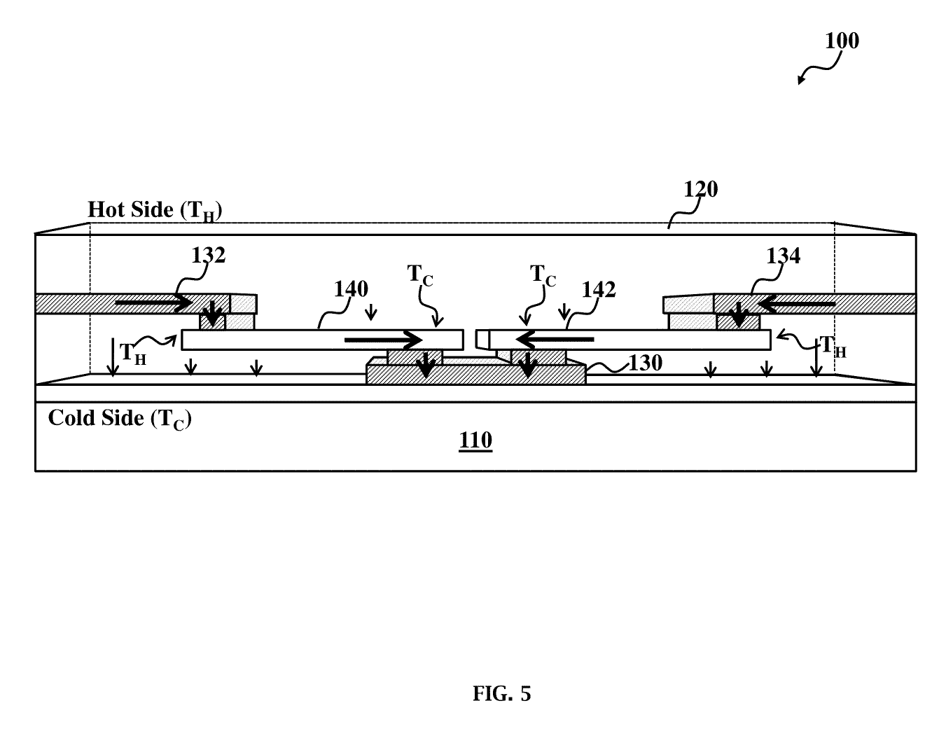

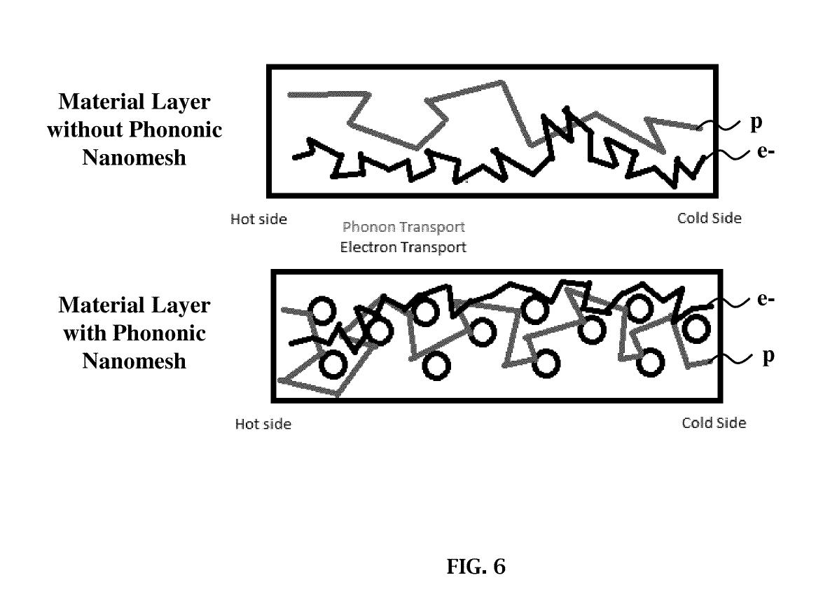

By minimizing the phonon component of thermal diffusion without impacting the transport of charge carriers, the phononic nanomeshes 150 and 152 reduce thermal conductivity without impacting electrical conductivity, thereby increasing the thermoelectric figure of merit and enhancing efficiency of the TEG 100 (improved efficiency in converting heat energy to electric energy). FIG. 6 illustrates an impact of a phononic nanomesh on phonon transport within a material layer. Such phenonema is further described in Jen-Kan Yu et al., “Reduction of Thermal Conductivity in Phononic Nanomesh Structures”, Nature Nanotechnology, 5, 718-721 (2010), the entire disclosure of which is hereby incorporated by reference. In FIG. 6, a phonon transport line (p) depicts a mean free path of phonons flowing through the material layer from a hot side to a cold side, and the charge carrier transport line (e−) depicts a mean free path of charge carriers flowing through the material layer from the hot side to the cold side. Where the material layer includes the phononic nanomesh, holes are disposed in the material layer with a periodicity comparable to the mean free path of the phonons. The holes reduce transport of the phonons from the hot side to the cold side of the material, thereby reducing thermal conductivity of the material. Because charge carriers (electrons and holes) flow through the material layer with a different mean free path than the phonons (in the present example, the charge carriers have a mean free path length that is less than the periodicity of the holes), the phononic nanomesh impacts phonon transport from the hot side to the cold side of the material layer with minimal impact on the charge carrier transport. The phononic nanomesh thus reduces thermal conductivity without impacting electrical conductivity. Accordingly, by implementing a phononic nanomesh in the TEG 100 (specifically in the semiconductor layers 142 and 144 of the thermocouple 140), a higher thermoelectric figure of merit is achievable, leading to an increase in energy conversion efficiency of the TEG 100. Ultimately, as described further below, the TEG 100 can be integrated with a solar cell to significantly improve overall conversion efficiency of a hybrid solar-thermal device (the TEG 100 integrated with a solar cell).

The proposed TEG structure, such as TEG 100, thus incorporates various features to improve conversion efficiency and expand its applications. In an example, forming the thermocouple of a TEG on a metal substrate imparts flexibility to the TEG so that the TEG can conform to any desired shape for various applications and the TEG can withstand higher operating temperatures. In another example, orienting the heat flux laterally through the thermocouple elements improves TEG conversion efficiency. In yet another example, modifying a nanostructure of the thermocouple elements to include a phononic nanomesh reduces phonon transport, thereby decreasing thermal conductivity and increasing the thermoelectric figure of merit without impacting electrical conductivity. The phononic nanomesh is easily incorporated into TEG structures having laterally-oriented heat flux, as compared to those having vertically-oriented heat flux.

An exemplary process for fabricating a TEG, such as the TEG 100, will now be described. The fabrication process facilitates building a TEG on a thin metal substrate, such as the thin metal substrate 110 of the TEG 100. For example, a metal substrate is prepared and provided. In the present example, a thermally conductive material, such as a Kovar metal foil is mounted to a silicon wafer and subjected to a chemical mechanical polishing (CMP) process to smooth a surface of the metal substrate. In an example, the Kovar metal foil (an iron-nickel-cobalt alloy) has a thickness of about 150 microns. A coefficient of thermal expansion of the Kovar metal foil matches that of silicon oxide, making it a great choice for a flexible substrate that can withstand high temperature uses. The Kovar metal foil can be cut using a UV laser into arbitrary shapes, for example the shape of a silicon wafer, and mounted onto a surface of a rigid silicon wafer for processing in semiconductor fabrication facilities. Using a polished foil results in high device yields, and processing of the foils is simplified, as the surface appearance was very similar to that of Si wafers. In an example, the unpolished Kovar metal foil has a peak-to-valley surface roughness that is several microns in magnitude, which is greater than a thickness of films used to construct the TEG, making it difficult to build layers over the Kovar metal foil without breaks or shorts in subsequently deposited conductive materials. The present process thus polishes the Kovar metal foil using the CMP process to remove any unwanted surface roughness. For example, the surface roughens of the Kovar metal foil is reduced to a few hundred nanometers. Thereafter, the polished Kovar metal foil is dismounted from the silicon wafer. The Kover metal foil may be subjected to a cleaning process, such as a sonic water bath or other cleaning process.

A series of dielectric thin film deposition and patterning processes, semiconductor deposition and patterning processes, and metal deposition and patterning processes are performed to form various features of the TEG (such as the electrodes and thermocouple of the TEG). In the present example, a thin dielectric film is formed over the polished surface of the Kovar metal foil by a chemical vapor deposition (CVD) process, a low pressure CVD process, a plasma enhanced CVD process, a physical vapor deposition process, other deposition process, or a combination thereof. The dielectric thin film provides electrical isolation of various components of the TEG from the Kovar metal foil. The dielectric thin film has a thickness from about 5 nm to about 100 nm. The dielectric thin film includes a dielectric material, such as those provided above with reference to the insulator layer 120 of the TEG 100.

A lithography patterning process is then performed to define a pattern in a resist layer over the dielectric thin film, the pattern defining dimensions of lower electrodes of the TEG. The lithography patterning processes include contact lithography, step and flash lithography, electron beam lithography, optical lithography, other types of lithography, or a combination thereof. A conductive material layer is then formed in the pattern of the resist layer to form the lower electrode of the TEG (such as the lower electrode 130 in the TEG 100). The conductive material layer has a thickness of about 50 nm to about 500 nm. The conductive material layer includes a thermally conductive material layer, such as those described above. In an example, the conductive material layer is formed using a PVD process, an evaporation process, other deposition process, or a combination thereof. Subsequently, a lift off process can be performed to remove the resist layer and any unwanted conductive material.

Thereafter, similar to the initially formed thin film dielectric layer, another thin film dielectric layer is formed over the conductive material layer. The dielectric thin film has a thickness from about 50 nm to about 1,000 nm. The dielectric thin film includes a dielectric material, such as those provided above with reference to the insulator layer 120 of the TEG 100. Lithography patterning and etching processes are then performed on the insulator layer 120 to define a pattern in the thin film dielectric layer that defines thermoelectric elements of the TEG (such as the n-type semiconductor layer and the p-type semiconductor layer). The lithography patterning processes include contact lithography, step and flash lithography, electron beam lithography, optical lithography, other types of lithography, or a combination thereof. The etching processes include plasma etch processes, reactive ion etch processes, other etch processes, or combinations thereof. An n-type semiconductor layer and a p-type semiconductor layer are then formed in respective patterns defined in the thin film dielectric layer a chemical vapor deposition (CVD) process, a low pressure CVD process, a plasma enhanced CVD process, a physical vapor deposition process, other deposition process, or a combination thereof. The n-type semiconductor layer and the n-type semiconductor layer have a thickness of about 50 nm to about 1,000 nm. In the present example, a separate thin film dielectric layer is formed and patterned for the n-type semiconductor layer and the p-type semiconductor layer, such that the process involves a first dielectric layer deposition; a via lithography, etch, and deposition process to form the n-type semiconductor layer in the first dielectric layer; a second dielectric layer deposition; and a via lithography, etch, and deposition process to form the p-type semiconductor layer.

Another thin film dielectric layer is then formed over the n-type and p-type semiconductor layers, and a lithography patterning process is then performed to define a pattern in a resist layer over the dielectric thin film, the pattern defining dimensions of upper electrode of the TEG. The thin film dielectric layer has a thickness of about 50 nm to about 1,000 nm. The lithography patterning processes include contact lithography, step and flash lithography, electron beam lithography, optical lithography, other types of lithography, or a combination thereof. A conductive material layer is then formed in the pattern of the resist layer to form the upper electrode of the TEG (such as the upper electrodes 132 and 134 in the TEG 100). The conductive material layer has a thickness of about 50 nm to about 500 nm. The conductive material layer includes a thermally conductive material layer, such as those described above. In an example, the conductive material layer is formed using a PVD process, an evaporation process, other deposition process, or a combination thereof. Subsequently, a lift off process can be performed to remove the resist layer and any unwanted conductive material. Another thin film dielectric layer may then be formed over the upper electrodes. The various thin film dielectric layers combine to form an insulator layer over the metal foil, such as the insulator layer 120 of the TEG 100. Another lithography patterning, etching, and deposition process can be performed to form electrical contacts to the upper electrode. The electrical contacts may be formed from a conductive material layer having a thickness of about 500 nm to about 5,000 nm.

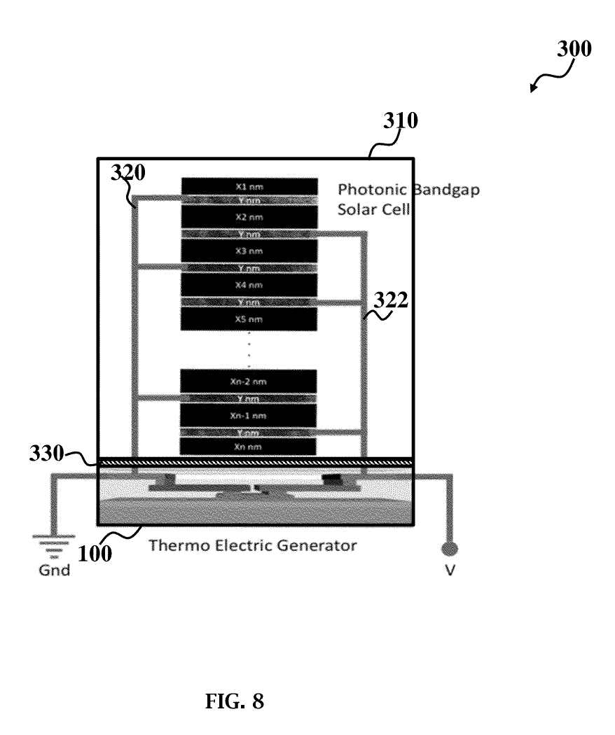

FIG. 8 is a diagrammatic view of a hybrid solar/thermal energy generation device 300, in portion or entirety, according to various aspects of the present disclosure. FIG. 8 has been simplified for the sake of clarity to better understand the inventive concepts of the present disclosure. For example, the various features depicted in FIG. 8 are not drawn to scale, but are exaggerated to provide clarity of the design of the hybrid solar/thermal energy generation device 300. Additional features can be added in the hybrid solar/thermal energy generation device 300, and some of the features described below can be replaced or eliminated for additional embodiments of the hybrid solar/thermal energy generation device 300.

In FIG. 8, the TEG 100 is integrated with a solar cell 310. In the depicted embodiment, the solar cell 310 is a photonic bandgap solar cell, such as a photonic bandgap solar cell described in detail in U.S. patent application Ser. No. 13/248,716 filed Sep. 29, 2011, entitled Photonic Bandgap Solar Cells, the entire disclosure of which is hereby incorporated by reference. The photonic bandgap solar cell disclosed in U.S. patent application Ser. No. 13/248,716 was made with Government support under Contract DARPA—W31P4Q-11-C-0237—Solar Cell, and the Government has certain rights in the solar cell patent application. The TEG 100 includes a flexible substrate (in the depicted embodiment, a metal substrate 110, such as a KOVAR metal foil substrate) that facilitates the TEG 100 conforming to a shape of the solar cell 310. The conformal TEG 100 is thus easily adhered to a variety of solar cells, including rigid and flexible solar cells, and solar cells of various shapes. In the depicted embodiment, the various material layers combining to form the solar cell 310 and TEG 100 (not including the substrate 110 of the TEG 100) are each a few hundred nanometers thick, such that a total thickness of the solar cell 310 and the TEG 100 (minus the substrate 110) is about 2 μm to about 5 μm and a thickness of the substrate 110 is about 150 μm. A total thickness of the hybrid solar/thermal energy generation device 300 (including substrate 110 of the TEG) is thus roughly equivalent to a diameter of a human hair.

The hybrid solar/thermal energy generation device 300 integrates circuits of the TEG 100 and the solar cell 310 so that both the TEG 100 and the solar cell 310 generate current. The solar cell 310 generates electricity from photonic energy, and the TEG 100 generates electricity from heat. In the present example, electrodes 320 and 322 extend along a length of the solar cell 310 and connect to the TEG 100. The electrodes 320 and 322 are made of a thermally conductive material, such as aluminum, gold, silver, copper, tungsten, zinc, nickel, platinum, palladium, other thermally conductive materials, or combinations thereof. In the depicted embodiment, the electrodes 320 and 322 include gold. The electrodes 320 and 322 effectively serve as a heat pipe that transfers heat generated in the solar cell 310 to the hot side of the TEG 100, where the TEG 100 converts this heat to additional current that is added to the integrated circuit of the hybrid solar/thermal energy generation device 300. Thus, heat generated within the solar cell 310 is transferred to the TEG 100, which converts the heat to electricity and simultaneously cools the solar cell 310. With the TEG 100 converting heat from the solar cell 310 into electricity, the monolithic hybrid solar/thermal energy generation device 300 exhibits improved electrical generation efficiency compared to the solar cell 310 alone or other conventional solar cells. For example, maximum theoretical efficiency of a multi-junction solar cell is about 55%, meaning that at least 45% of energy incident on the solar cell is lost to heat. By integrating the TEG 100 with a solar cell device, such as the solar cell 310, at least a portion of heat typically lost by the solar cell is converted into electricity by the TEG 100, making the hybrid solar/thermal energy generation device 300 significantly more effective at energy generation compared to solar cell devices alone.

In the depicted embodiment, the solar cell 310 is fabricated directly onto the TEG 100. For example, the solar cell 310 is attached to the TEG 100 via a thermally conductive adhesive layer 330. The thermally conductive adhesive layer 330 maximizes heat transfer between the solar cell and the TEG 100. In the depicted embodiment, the thermally conductive adhesive layer 330 is a silver nanoparticle adhesive layer. The silver nanoparticle adhesive layer can withstand very high temperatures (for example, approximately 900° C.) while retaining excellent thermal characteristics. In the illustrated embodiment, a suspension of silver nanoparticles mixed with a solvent is used as the silver nanoparticle adhesive layer. The silver nanoparticles can be in the form of liquids and pastes. A viscosity of the paste can be tailored for its application. For example, the paste has a viscosity of approximately 100,000 centipoise where it will be implemented for screen printing. By applying modest heat (for example, from about 150° C. to about 200° C.) and pressure, the silver nanoparticles are sintered and fuse to each other and neighboring materials to form a strong, very high thermally conductive bond between the solar cell 310 and the TEG 100.

An exemplary process for attaching (adhering or bonding) the solar cell 310 to the TEG 100 via a silver nanoparticle paste (such as a suspension of silver nanoparticles mixed with a solvent) is now described. A gold layer is formed on a bonding surface of the solar cell 310 and a bonding surface of the TEG 100. In an example, the gold layer has a thickness of about 0.1 μm to about 1 μm. The gold layer is applied to the bonding surfaces using a sputtering process, an electroplating process, other process, or combination thereof. The gold layer should be well adhered to the bonding surfaces. The silver nanoparticle paste is then applied to the bonding surface of the solar cell 310, the bonding surface of the TEG 100, or both bonding surfaces. In an example, the silver nanoparticle paste is applied to the bonding surfaces using a screen printing or other method that results in a silver nanoparticle paste layer having a smooth surface of generally uniform thickness, such as a thickness of about 50 μm to about 150 μm. Then, the solvent is outgassed from the silver nanoparticle paste by a heating process. In an example, the heating process heats the silver nanoparticle paste to a temperature of about 60° C. for approximately one hour. Care should be taken to during processing to ensure that minimal to no dust falls on the wet silver nanoparticle paste. The solar cell 310 and TEG 100 are then clamped together, such that the bonding surfaces are pressed together. In an example, the solar cell 310 and TEG 100 are clamped together with a pressure of approximately 5 megaPascals. While clamped together, the solar cell 310 and TEG 100 are heated to a temperature of about 150° C. for about four hours. The heating bonds the solar cell 310 to the TEG 100 via the silver nanoparticle adhesive layer. Since the silver nanoparticle adhesion process is one of sintering, other combinations of time, temperature, and pressure are contemplated for affecting the bonding between solar cell 310 and the TEG 100.

The hybrid solar/thermal energy generation device 300 is particularly useful for space applications. For example, the very thin nature of the TEG 100 and the hybrid solar/thermal energy generation device 300 contributes insignificant additional weight or size to existing solar panels. Alternatively, the more efficient electric generation system could be made smaller than existing devices while producing the same amount of electricity, reducing weight and saving launch costs. The more efficient and smaller device has important application on smaller satellite platforms, for example “cube sats,” and micro and nano satellites. Further, the hybrid solar/thermal energy generation device 300 can accept light and heat from natural sources (such as the sun) and from man-made sources (such as lasers). In one scenario, NASA is interested in providing electrical power to spacecraft using a high-energy laser as the power source. In this scenario, the intent is to send photonic and thermal energy from a laser beam generated from earth and capture that energy on a satellite in space using a solar/thermal power generation system. In this scenario, the temperature gradient is even higher than that generated from solely a solar source. The hybrid solar/thermal energy generation device 300 described herein is ideal for such an application because it has the flexibility to conform to an optimal shape for accepting a laser beam regardless of incident angle of the energy and it can operate at very high temperatures. The following discussion provides various solar cell designs for optimizing and maximizing efficient conversion of monochromatic light to electricity compared to the broad-band operation covering the solar spectrum. Overall efficiency and thermal management benefits by implementing the concepts herein result in significant gains in electric power generation over current systems.

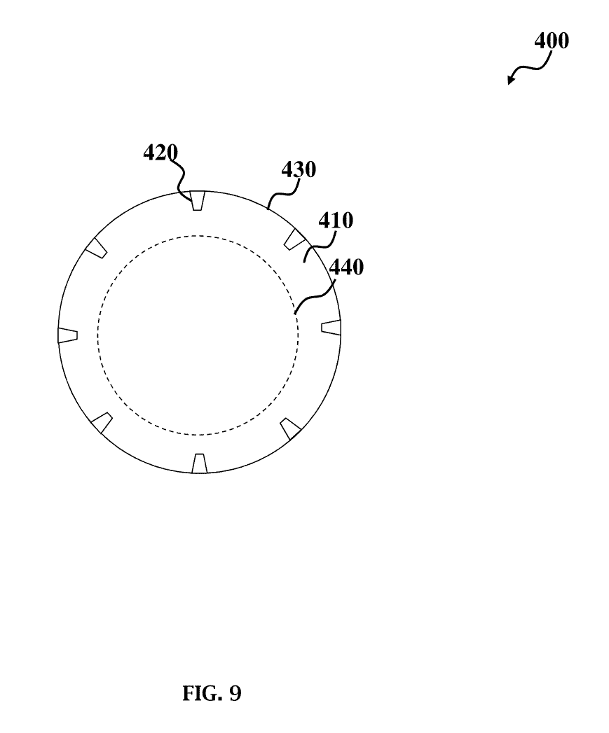

FIG. 9 illustrates a solar panel 400 that implements an integrated TEG/solar cell device, such as the hybrid solar/thermal energy generation device 300, in portion or entirety, according to various aspects of the present disclosure. FIG. 9 has been simplified for the sake of clarity to better understand the inventive concepts of the present disclosure. Additional features can be added in the solar panel 400, and some of the features described below can be replaced or eliminated for additional embodiments of the solar panel 400.

The solar panel 400 has an energy receiving surface 410 formed by an integrated TEG/solar cell system. For example, the energy receiving surface 410 consists of numerous hybrid solar/thermal energy generation devices 300 combined to form the energy receiving surface 410. Energy sensors 420 are positioned around a perimeter 430 of the solar panel 400. Each of the sensors 420 can be formed of a temperature and irradiance sensor matrix such as that disclosed in (1) U.S. Patent Application Publication No. 2012/0062872 filed Sep. 30, 2009 entitled Mesh Sensor for Measuring Directed Energy and (2) U.S. patent application Ser. No. 12/405,998 filed Mar. 17, 2009 entitled Mesh Sensor for Measuring Directed Energy, the entire disclosures of which are hereby incorporated by reference. In FIG. 9, a laser irradiates the solar panel 400 with a laser beam, depicted as laser energy spot 440 upon the energy receiving surface 410. For maximum energy transfer, an entire circumference of the laser energy irradiation (laser energy spot 440) is incident on the solar panel 400. The energy sensors 420 situated around the perimeter 430 of the solar panel 400 assist with aiming the laser from a ground station or adjusting a position of the solar panel 400 relative to the laser beam incident thereon. The laser beam (laser energy spot 440) is not centered on the solar panel 400 if the laser beam irradiates one or more of the energy sensors 420. The energy sensors 420 provide information to a controller associated with the laser and the solar panel 400 to ensure the entire circumference of the laser beam irradiates the energy receiving surface 410. The energy sensors 420 thus facilitate adjusting the position of the solar panel 400 relative to the laser beam or adjusting the position of the laser beam relative to the solar panel 400. In a further aspect, the laser beam intentionally irradiates the energy sensors 420 to evaluate an amount of laser irradiance and/or thermal energy supplied to the solar panel 400. Based on this information, certain laser beam attributes can be adjusted to obtain maximize efficiency of the solar panel 800 without damaging its components. Further, this information allows the solar panel system to determine the efficiency of the solar panel 400 based on the amount of energy actually supplied by the laser beam incident on the solar panel 400 (the laser energy spot 440).

It is very challenging to create a single solar cell or laser cell that maximizes efficiency for converting both broadband light and monochromatic light to electricity. The present disclosure thus proposes solar/energy collector systems that incorporate solar cells and laser cells for efficient conversion of both solar energy and laser energy into electrical energy. The disclosed solar/energy collector systems have geometric designs that combine two different types of solar cells to maximize conversion of both solar energy and laser energy into electrical energy. More specifically, the disclosed solar/energy collector systems incorporate photonic bandgap solar cells, such as the photonic bandgap solar cell 310 described above, for collecting solar energy and Fabry Perot photovoltaic cells for collecting laser light (such as monochromatic laser light). Combining a nanoscale thin film design for solar energy collection (such as the photonic bandgap solar cell described above) and enhanced Fabry Perot photovoltaic cells for monochromatic laser light collection maximizes efficiency of the solar/energy collector systems described herein. The designs take advantage of the fact that the photonic bandgap solar cell is highly reflective in the near infrared (NIR) region and is not angular dependent, such that the photonic bandgap solar cell retains good efficiency on curved or angled surfaces. These features of the photonic bandgap solar cell are more fully described in U.S. patent application Ser. No. 13/248,716 filed Sep. 29, 2011, entitled Photonic Bandgap Solar Cells, the entire disclosure of which is hereby incorporated by reference. Further, the solar/energy collector systems integrate TEGs, such as the TEG 100, with the solar cells (the photonic bandgap solar cells, the Fabry Perot photovoltaic cells, or both) to further maximize energy conversion of the solar/energy collector systems.

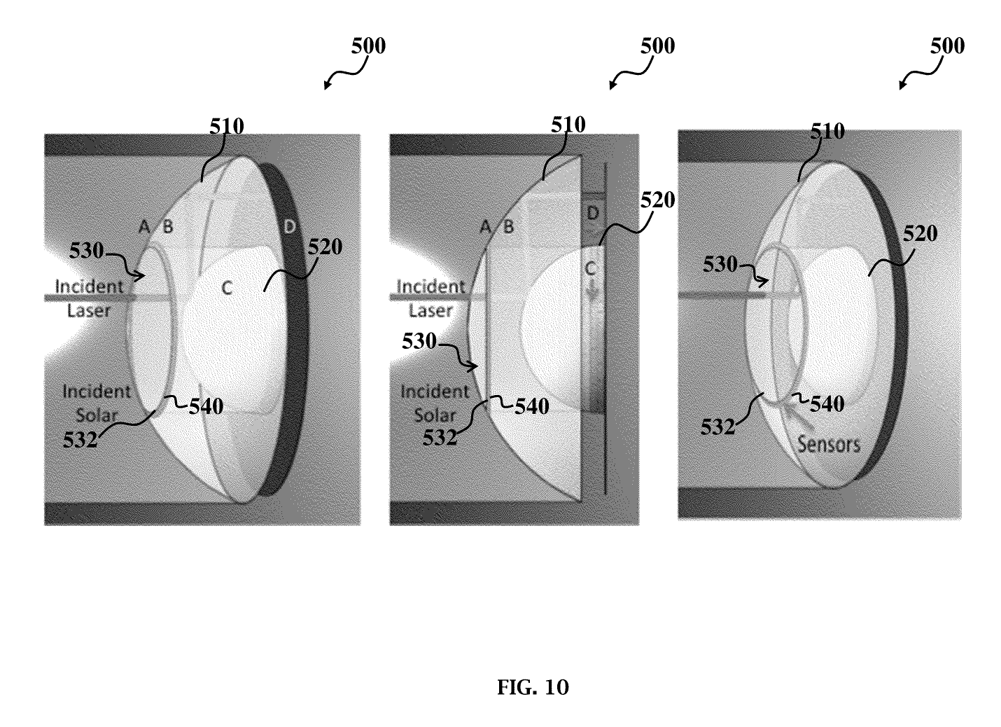

FIG. 10 includes various views of a solar/laser energy collector system 500, in portion or entirety, according to various aspects of the present disclosure. The energy collector system 500 includes a two-dome energy collector system that captures both solar energy and laser energy. FIG. 10 has been simplified for the sake of clarity to better understand the inventive concepts of the present disclosure. For example, sizes and shapes of the various features of the solar/laser energy collector system 500 are not to scale and are meant only to convey the solar/laser energy collection concepts described herein. Both solar energy and laser energy irradiate the solar/laser energy collector system 500, and thus, an optimal optical design of the solar/laser energy collector system 500 ensures maximum light capture (in other words, maximum solar energy and laser energy capture) of the solar/laser energy collector system 500. Additional features can be added in the solar/laser energy collector system 500, and some of the features described below can be replaced or eliminated for additional embodiments of the solar/laser energy collector system 500.

In FIG. 10, the solar/laser energy collector system 500 includes two concentric domes, an outer dome 510 having a surface A and a surface B and an inner dome 520 having a surface C. Solar cells cover the surface A of the outer dome 510, surface C of the inner dome 520, and surface D of the solar/laser energy collector system 500. In the depicted embodiment, the surfaces A and C are covered with photonic bandgap solar cells, such as the photonic bandgap solar cell 310 described above, and the surface D is covered with Fabry Perot photovoltaic cells. Because photonic bandgap solar cells can convert solar energy to electrical energy despite an incidence angle of the solar energy (in other words, the photonic bandgap solar cells are not angular dependent), the photonic bandgap solar cells efficiently converts solar energy incident thereon to electrical energy. Further, because the surface D is covered with the Fabry Perot photovoltaic cells, the solar/laser energy collector system 500 can also efficiently convert laser energy to electrical energy. The surface B of the outer dome 510 is covered with a reflective feature, for example, various mirrored surfaces that reflect light incident thereon. In an example, the mirrored surfaces are backsides of the solar cells covering the surface A of the outer dome 510. In an example, the mirrored surfaces are backsides of TEGs integrated with the solar cells covering the surface A of the outer dome 510.

An aperture 530 defined by a ring 532 is included in a central area of the outer dome 510 so that laser energy can enter the solar/laser energy collector system 500. The central area of the outer dome 510 is thus not covered with solar cells. Laser energy incident on the solar/laser energy collector system 500 enters the aperture 530 in the outer dome 510 (surface A), reflects from the solar cells covering the inner dome 520 (surface C) onto the mirrored surfaces of the outer dome 510 (surface B), and reflects from the mirrored surfaces of the outer dome 510 (surface B) onto the solar cells covering the surface D of the solar/laser energy collector system 500. Such design captures both solar energy and laser energy, while ensuring that any spurious reflections from the incident laser beam are limited since any reflected laser energy is scattered by the curved surfaces of the solar/laser energy collector system 500. Further, the disclosed concentric two dome design disperses the incident laser beam such that a surface area of the laser energy incident on the surface D (covered with the Fabry Perot photovoltaic cells) is larger than a surface area of the incident laser beam spot. The increase in surface area (from the incident laser beam spot size to the incident laser beam spot size on the surface D) facilitates higher intensity laser beam without damaging the Fabry Perot photovoltaic cells or surrounding materials of the solar/laser energy collector system 500. The solar/laser energy collector system 500 provides useful space applications, for example, the solar/laser energy collector system can supplement power to a spacecraft or other system associated therewith. In the depicted embodiment, the solar cells covering the surface A, surface C, and/or surface D are integrated with TEGs, such as TEG 100 described above, such that the surfaces A, C, and/or D are covered with hybrid solar/thermal energy generation devices. For example, the surfaces A, C, and D are covered with the hybrid solar/thermal energy generation devices 300 described above, where the hybrid solar/thermal energy generation devices covering surfaces A and C include photonic bandgap solar cells integrated with TEGs, and the hybrid solar/thermal energy generation device covering surface D include Fabry Perot photovoltaic cells integrated with the TEGs. Integrating the TEGS with the solar cells covering the various surfaces of the solar/laser energy collection system 500 increases conversion efficiency of the solar/laser energy collection system.

In furtherance of the depicted embodiment, sensors 540 are disposed along the surface A of the inner dome 510. The sensors 540 surround the ring 532 defining the aperture 530. The ring of sensors 540 assists with alignment of the incident laser beam. For example, the sensors 540 assist with centering the incident laser beam through the aperture 530, such that laser energy incident on the surface C of the inner dome 520 is maximized, thereby maximizing laser energy incident on the surface D of the solar/laser energy collector system 500. Maximizing the laser energy incident on the surface D increases an amount of laser energy for conversion to electrical energy by the Fabry Perot photovoltaic cells covering the surface D of the solar/laser energy collector system 500. In space applications, the sensors 540 can identify a position of the incident laser beam relative to the solar/laser energy collector system 500 to that the spacecraft can be oriented relative to the solar/laser energy collector system 500 to center the incident laser beam in the aperture 530.

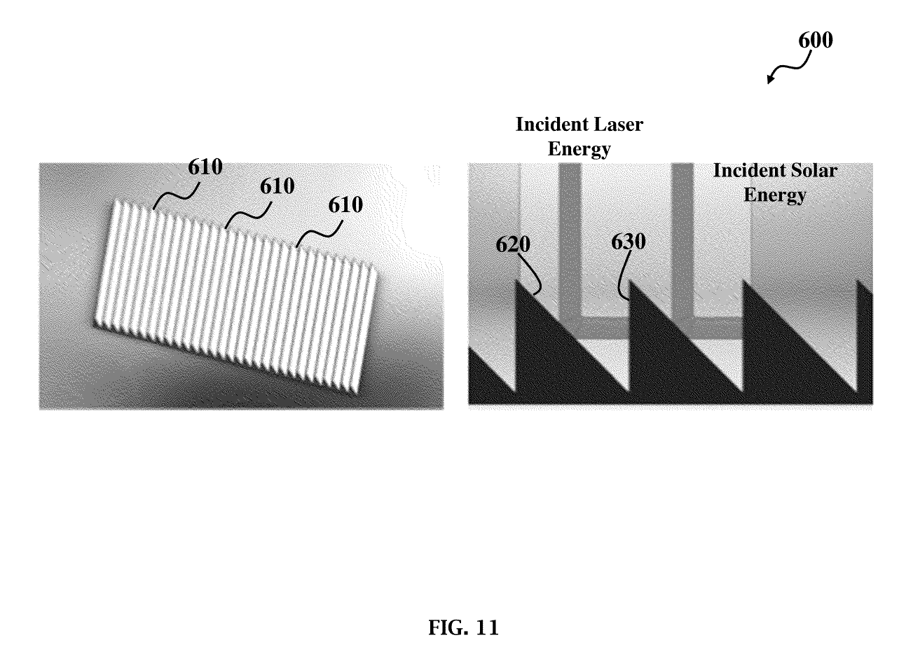

FIG. 11 includes various views of a solar/laser energy collector system 600, in portion or entirety, according to various aspects of the present disclosure. The solar/laser energy collector system 600 includes captures both solar energy and laser energy. In particular, the solar/laser energy collector system 600 takes advantage of a reflective nature of solar cells in a near infrared (NIR) region to capture multiple energy wavelength bands. FIG. 11 has been simplified for the sake of clarity to better understand the inventive concepts of the present disclosure. For example, sizes and shapes of the various features of the solar/laser energy collector system 600 are not to scale and are meant only to convey the solar/laser energy collection concepts described herein. Both solar energy and laser energy irradiate the solar/laser energy collector system 600, and thus, an optimal optical design of the solar/laser energy collector system 600 ensures maximum light capture (in other words, maximum solar energy and laser energy capture) of the solar/laser energy collector system 600. Additional features can be added in the solar/laser energy collector system 600, and some of the features described below can be replaced or eliminated for additional embodiments of the solar/laser energy collector system 600.

In FIG. 11, the solar/laser energy collector system 600 includes protrusions 610 having an angled surface 620 and a vertical surface 630. Solar cells cover the angled surface 620 and the vertical surface 630. In the depicted embodiment, the angled surface 620 is covered with photonic bandgap solar cells, such as the photonic bandgap solar cell 310 described above, and the vertical surface 630 is covered with Fabry Perot photovoltaic cells. Because photonic bandgap solar cells can convert solar energy to electrical energy despite an incidence angle of the solar energy (in other words, the photonic bandgap solar cells are not angular dependent), the photonic bandgap solar cells efficiently collect solar energy incident thereon and convert it to electrical energy. Further, because the vertical surface 630 is covered with the Fabry Perot photovoltaic cells, the solar/laser energy collector system 600 can also efficiently convert laser energy to electrical energy. For example, in FIG. 11, laser energy incident on the angled surface 620 reflects from the solar cells covering the angled surface 620 (here, the photonic bandgap solar cells) onto the vertical surface 630, wherein the Fabry Perot photovoltaic cells collect the laser energy and convert it to electrical energy. In the depicted embodiment, the solar cells covering the angled surface 620 and the vertical surface 630 are integrated with TEGs, such as TEG 100 described above, such that the angled surface 620 and/or the vertical surface 630 are covered with hybrid solar/thermal energy generation devices. For example, the angled surface 620 is covered with the hybrid solar/thermal energy generation devices 300 described above, where the hybrid solar/thermal energy generation devices covering the angled surface 620 includes photonic bandgap solar cells integrated with TEGs, and the hybrid solar/thermal energy generation devices covering vertical surface 630 include Fabry Perot photovoltaic cells integrated with the TEGs. Integrating the TEGS with the solar cells covering the various surfaces of the solar/laser energy collection system 600 increases conversion efficiency of the solar/laser energy collection system 600.

The TEG device 100 and hybrid solar/thermal energy generation device 300 described herein is not limited to space-based applications. For example, terrestrial solar panels also suffer from reduced conversion efficiency when they get hot. Further, a thermal component of energy absorbed by terrestrial solar panels is simply wasted heat. By integrating the TEG 100 described herein with the solar cells thermal management and improved energy harvesting is realized for solar arrays, solar roof tiles, solar battery chargers (cars and electronics), remote instrumentation, and other solar powered applications. In yet other applications, the TEG 100 is used alone as a “skin” on any heat source to provide potentially large improvements in energy harvesting. This is particularly useful for industrial and automotive applications where there is considerable waste heat. As an example, the TEG concept is also relevant for concentrator solar cell operations. In principle, efficiency of concentrator solar cell devices is increased where sunlight is concentrated onto a small area. This is usually done for tandem solar cells where surface areas are small. However, use of solar cell concentrators is limited due to heating of the solar cell from the concentrated light. The TEGs described herein, such as TEG 100, can be integrated with solar cells of the solar cell concentrators to cool the solar cells and convert waste heat into electricity. Yet a further application of the TEG is in a cooling side of steam powered electric generators. In order to convert steam to water, a large amount of thermal energy is transferred to the environment through water cooling towers or other mechanisms. The flexible TEG devices described herein can be integrated with high temperature pipes and work with existing cooling systems to provide thermal transfer. In addition to the benefit of the electrical energy generated by the TEG devices described herein, less thermal energy would be added to the surrounding environment. In still a further application, heat sources can be created with the TEG devices attached thereto, for example, a small cavity that uses combustible fuels to create heat. The flexible TEG and hybrid solar/thermal energy generation devices described herein also offer an opportunity for small-scale implementation of waste energy capture from solar cells and other heat sources, and integration of such systems onto existing equipment. If the concepts described herein significantly improve efficiency of devices and systems integrated therewith, a return on investment arises on a cost of implementing the energy recovery system. This technology thus also offers an economic opportunity for improved efficiency, strategic opportunity for reduced oil and coal consumption rates, and environmental opportunity for lower carbon emissions and smog.

The present disclosure thus provides a device and method for combining flexible TEGs with flexible solar cells. The design described herein is particularly attractive due to its modular and scalable design with no working fluids. Where the solar cell integrated with the disclosed TEG is a photonic bandgap, multi-junction device, higher conversion efficiencies with lower manufacturing costs are achieved compared to current thin film solar cells. As described in detail herein, the disclosed TEG incorporates a lateral design that facilities very long thermoelectric elements compared to standard vertical design of TEGs. Further, the hybrid solar/thermal energy harvesting devices and methods described herein (1) dramatically increase efficiency of solar and thermal energy harvesting, (2) are fabricated on flexible metal foils that are easily adapted to heat sources of arbitrary geometry, and (3) offer high temperature operation. Such features result in devices that can recover a largely untapped source of waste heat from solar panels for conversion into electricity. The high temperature operation combined with phonon limitation of nano-structured materials provides superior conversion efficiencies compared to solar cells alone. Further, the monolithic solar cell and TEG device described herein have no moving parts and therefore are very reliable. Even further, tiles of micro-fabricated energy harvesting arrays can be scaled using the disclosed TEG/solar cell integrated devices described herein, making them ideal for small, distributed power generation.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A thermoelectric generator comprising:
an upper electrode;
a lower electrode; and
a thermocouple disposed between the upper electrode and the lower electrode, wherein the upper electrode, the lower electrode, and the thermocouple are configured to effect heat flux laterally through the thermocouple.

2. The thermoelectric generator of claim 1 wherein the thermocouple includes:
a n-type semiconductor layer electrically and thermally coupled with the upper electrode and the lower electrode; and
a p-type semiconductor layer electrically and thermally coupled with the upper electrode and the lower electrode.

3. The thermoelectric generator of claim 2 wherein:
the lower electrode is coupled with a cold end respectively of the n-type semiconductor layer and the p-type semiconductor layer;
the upper electrode is coupled with a hot end respectively of the n-type semiconductor layer and the p-type semiconductor layer;
the cold end and hot end of the n-type semiconductor layer are oriented along a length of the n-type semiconductor layer; and
the cold end and hot end of the p-type semiconductor layer are oriented along a length of the p-type semiconductor layer.

4. The thermoelectric generator of claim 2 wherein the n-type semiconductor layer, the p-type semiconductor layer, or both includes a phononic nanomesh.

5. The thermoelectric generator of claim 2 wherein the n-type semiconductor layer and the p-type semiconductor layer have a same thickness and a same length, the length being greater than the thickness.

6. The thermoelectric generator of claim 5 wherein:
the upper electrode and the lower electrode have a same thickness; and
the length of the n-type semiconductor layer and the p-type semiconductor layer designed to minimize an effect associated with the thickness of the upper electrode and the lower electrode on conversion efficiency.

7. The thermoelectric generator of claim 1 further comprising:
a metal substrate; and
an insulator layer disposed over the metal substrate, wherein the upper electrode, the lower electrode, and the thermocouple are disposed in the insulator layer.

8. The thermoelectric generator of claim 1 wherein the thermocouple includes a pair of thermoelectric elements, each of the thermoelectric elements having a length, and wherein the thermoelectric elements are arranged to achieve a temperature gradient along the length.

9. A thermoelectric generator comprising:
a metal substrate;
an insulator layer disposed over the substrate;
an upper electrode and a lower electrode disposed in the insulator layer; and
a thermocouple disposed in the insulator layer between the upper electrode and the lower electrode, wherein the thermocouple includes:
an n-type semiconductor layer coupled with the upper electrode and the lower electrode, and
a p-type semiconductor layer coupled with the upper electrode and the lower electrode; and
wherein the n-type semiconductor layer, the p-type semiconductor layer, the upper electrode, and the lower electrode are configured to achieve a temperature gradient along a length of the n-type semiconductor layer and the p-type semiconductor layer.

10. The thermoelectric generator of claim 9 wherein one of the n-type semiconductor layer, the p-type semiconductor layer, or both include a phononic nanomesh.

11. The thermoelectric generator of claim 9 wherein the n-type semiconductor layer and the p-type semiconductor layer have a same thickness and a same length, the length being greater than the thickness.

12. The thermoelectric generator of claim 11 wherein:
the upper electrode contacts hot ends of the n-type semiconductor layer and the p-type semiconductor layer;
the lower electrode contacts cold ends of the n-type semiconductor layer and the p-type semiconductor layer; and
wherein the cold end and hot end of the n-type semiconductor layer are oriented along the length of the n-type semiconductor layer; and
the cold end and hot end of the p-type semiconductor layer are oriented along the length of the p-type semiconductor layer.

13. The thermoelectric generator of claim 12 wherein:
the upper electrode and the lower electrode have a same thickness; and
the length of the n-type semiconductor layer and the p-type semiconductor layer designed to minimize an effect associated with the thickness of the upper electrode and the lower electrode on conversion efficiency.

14. A solar/thermal energy conversion device comprising:
a solar cell for generating electricity from photonic energy; and
a thermoelectric generator electrically and thermally coupled with the solar cell such that the thermoelectric generator converts a portion of heat generated by the solar cell into electricity.

15. The solar/thermal energy conversion device of claim 14 wherein the solar cell is a photonic bandgap solar cell.

16. The solar/thermal energy conversion device of claim 14 wherein a silver nanoparticle adhesive attaches the solar cell to the thermoelectric generator.

17. The solar/thermal energy conversion device of claim 14 wherein the thermoelectric generator includes thermocouple elements configured to achieve laterally-oriented heat flux.

19. The solar/thermal energy conversion device of claim 14 wherein the solar cell includes an electrode connected to a hot side of the thermoelectric generator, wherein the electrode transfers heat from the solar cell to the hot side of the thermoelectric generator.

20. The solar/thermal energy conversion device of claim 14 wherein the thermoelectric generator includes:
an upper electrode;
a lower electrode; and
a thermocouple disposed between the upper electrode and the lower electrode, wherein the upper electrode, the lower electrode, and the thermocouple are configured to effect heat flux laterally through the thermocouple.
